(19) United States
(12) Patent Application Publication
(10) Pub. No.: US 2024/0200224 A1
(43) Pub. Date: Jun. 20, 2024

(54) INGOT GROWING APPARATUS

(71) Applicant: HANWHA SOLUTIONS CORPORATION, Seoul (KR)

(72) Inventors: Jin Sung PARK, Seoul (KR); Han Woong JEON, Seoul (KR); Kyung Seok LEE, Seoul (KR); Keun Ho KIM, Seoul (KR); Young Min LEE, Seoul (KR)

(21) Appl. No.: 18/555,514

(22) PCT Filed: Aug. 31, 2022
(86) PCT No.: PCT/KR2022/013040

§ 371 Date: Oct. 14, 2023

(30) Foreign Application Priority Data
Oct. 18, 2021 (KR) 10-2021-0138666

(51) Int. Cl. C30B 15/04; C30B 15/00; C30B 29/06

(52) U.S. Cl. CPC C30B 15/04; C30B 15/002; C30B 29/06

(57) ABSTRACT

An ingot growing apparatus, according to an embodiment of the present invention, comprises: a growth furnace in which a main crucible accommodating molten silicon for growing an ingot is disposed; a preliminary melting part which receives and melts a solid silicon material and a dopant, and has a preliminary crucible that supplies the molten silicon to the main crucible; a transfer part which transfers the solid silicon material and the dopant to the preliminary crucible; a silicon supply part which supplies the solid silicon material to the transfer part; and a dopant supply part which is disposed on an upper side of the transfer part and supplies the dopant to the transfer part according to a concentration of the dopant melted in the main crucible.

### TECHNICAL FIELD

The present invention relates to an ingot growing apparatus, and more specifically to an ingot growing apparatus for growing an ingot by supplying solid silicon and a dopant.

### BACKGROUND ART

Single-crystal silicon is used as a basic material for most semiconductor components, and these materials are manufactured as single crystals with high purity, and one of the manufacturing methods thereof is the Czochralski method.

In the Czochralski crystal method, a solid silicon material and a dopant are placed in a crucible in a chamber, and the susceptor is heated by using a heating element to melt the silicon and the dopant. In addition, when a single-crystal seed is pulled up through a wire in an upward direction while rotating in a state of being in contact with this molten silicon, an ingot having a predetermined diameter is grown through a crown process in which the diameter is increased to approach the target diameter of the ingot.

The Continuous Czochralski method (CCz), which is one of the Czochralski methods, is a method of continuously injecting solid polysilicon and a dopant into a crucible to continuously grow an ingot.

However, when an ingot is grown through the Continuous Czochralski method, dopants are not uniformly distributed in the ingot, and there is a problem in that the yield and quality of the ingot are reduced.

### DISCLOSURE

### Technical Problem

The present invention has been devised to solve the above problems, and is directed to providing an ingot growing apparatus for controlling the supply of a dopant such that the dopant is uniformly distributed in an ingot.

In addition, the present invention is directed to providing an ingot growing device which is capable of managing the quality and yield of ingots at constant levels.

### Technical Solution

In order to solve the above problems, the ingot growing apparatus according to an exemplary embodiment of the present invention may include a growth furnace in which a main crucible accommodating molten silicon for growing an ingot is disposed; a preliminary melting part which receives and melts a solid silicon material and a dopant, and has a preliminary crucible that supplies the molten silicon to the main crucible; a transfer part which transfers the solid silicon material and the dopant to the preliminary crucible; a silicon supply part which supplies the solid silicon material to the transfer part; and a dopant supply part which is disposed on an upper side of the transfer part and supplies the dopant to the transfer part according to a concentration of the dopant melted in the main crucible.

In this case, the dopant supply part may include a body part which is disposed on an upper side of the transfer part; and a dopant transfer part which is disposed inside the body part and accommodates the dopant to control supply of the dopant.

In this case, the dopant transfer part may include a first rotation part which is disposed inside the body part and rotated in a clockwise or counterclockwise direction; a second rotation part which is disposed to be spaced apart from the first rotation part inside the body part and rotated in the same direction as the first rotation part; a belt which is in contact with the first rotation part and the second rotation part and rotated by the first rotation part and the second rotation part; a plurality of dopant supporting parts which are disposed on an outer side of the belt; and a plurality of dopant accommodating parts which are rotatably connected to each of the plurality of dopant supporting parts and accommodate the dopant

In this case, the dopant transfer part may further include a locking part which is disposed on a lower side of the body part and contacts the dopant accommodating part to rotate the dopant accommodating part.

In this case, the dopant supporting part may include a first support part which is coupled to an outer side of the belt; a first rotational shaft which is disposed on one side of the first support part; and a second support part which is rotatably connected to the first rotation shaft.

In this case, the dopant accommodating part may include a first accommodating part which is made of a flat plate shape; a second accommodating part which extends from the first accommodating part and is formed to be inclined at a predetermined angle with the first accommodating part; and a second rotational shaft which is rotatably connected to the second support part and disposed between the first accommodating part and the second accommodating part, wherein the dopant accommodating part may be rotated in a clockwise direction or counterclockwise direction about the second rotational shaft.

In this case, when the dopant supporting part rotates along the belt and abuts the locking part, the distance between the center of the first rotational shaft and the center of the second rotational shaft may be greater than the distance between the center of the first rotational shaft and the center of the locking part.

In this case, the speed reducing part may include a discharge pipe which is connected to a lower side of the body part; and a plurality of protrusions which protrude from an inner side surface of the discharge pipe and contact the dopant falling in the direction of gravity.

In this case, the plurality of protrusions may include a plurality of first protrusions which are formed to narrow along the direction of gravity; and a plurality of second protrusions which are disposed to be spaced apart from the plurality of first protrusions and are disposed to be spaced apart from each other along the direction of gravity.

### Advantageous Effects

In the ingot growing apparatus according to an exemplary embodiment of the present invention, the supply of a dopant is controlled according to the concentration of a dopant melted in the main crucible such that the dopant is uniformly distributed in an ingot, and the quality and yield of the ingot are improved.

### DESCRIPTION OF DRAWINGS

FIG. 1 is a view schematically showing the ingot growing apparatus according to an exemplary embodiment of the present invention.

FIG. 2 is a diagram showing the dopant transfer part illustrated in FIG. 1.

FIG. 3 is an enlarged view of A indicated in FIG. 2.

FIG. 4 is a view showing a state in which the dopant supporting part is adjacent to the locking part.

FIG. 5 is a view showing a state in which the dopant accommodating part contacts the locking part.

FIG. 6 is a view showing how the dopant accommodating part rotates.

FIG. 7 is a diagram showing a process in which the dopant falls from the dopant accommodating part.

FIG. 8 is a view showing the fall reducing part illustrated in FIG. 1.

### MODES OF THE INVENTION

Hereinafter, various exemplary embodiments will be described in more detail with reference to the accompanying drawings. The exemplary embodiments according to the present invention may be modified in various forms. A specific exemplary embodiment may be illustrated in the drawings and may be described in detail in the detailed description. However, the specific exemplary embodiment disclosed in the accompanying drawing is merely provided for easy understanding of various exemplary embodiments. Accordingly, it should be understood that the technical spirit is not limited by the specific exemplary embodiment disclosed in the accompanying drawing, but includes all equivalents or alternatives included in the spirit of and the technical scope of the present invention.

Terms including an ordinary number, such as first and second, are used for describing various constituent elements, but the constituent elements are not limited by the terms. The above terms are used only to discriminate one component from the other component.

In the exemplary embodiments of the present invention, it should be understood that terminology such as “include” or “have” indicates that a feature, a number, a step, an operation, a component, a part or the combination thereof described in the exemplary embodiments of the present invention is present, but does not exclude a possibility of presence or addition of one or more other features, numbers, steps, operations, components, parts or combinations, in advance. It should be understood that, when it is described that an element is “coupled” or “connected” to another element, the element may be directly coupled or directly connected to the other element, or coupled or connected to the other element through a third element. In contrast, when it is described that an element is “directly coupled” or “directly connected” to another element, it should be understood that no element is present therebetween.

Meanwhile, “module” or” “part” for components used in the exemplary embodiments of the present invention performs at least one function or operation. In addition, “module” or “part” may perform a function or an operation by software or a combination of hardware and software. In addition, a plurality of “modules” or a plurality of “parts” excluding “module” or “part” which has to be executed in a specific hardware or is executed in at least one processor may be integrated as at least one module. A singular expression may include a plural expression if there is no clearly opposite meaning in the context.

Further, in the description of the exemplary embodiments of the present invention, the detailed description of known configurations or functions incorporated herein will be contracted or omitted, when it is determined that the detailed description may make the gist of the present invention unclear.

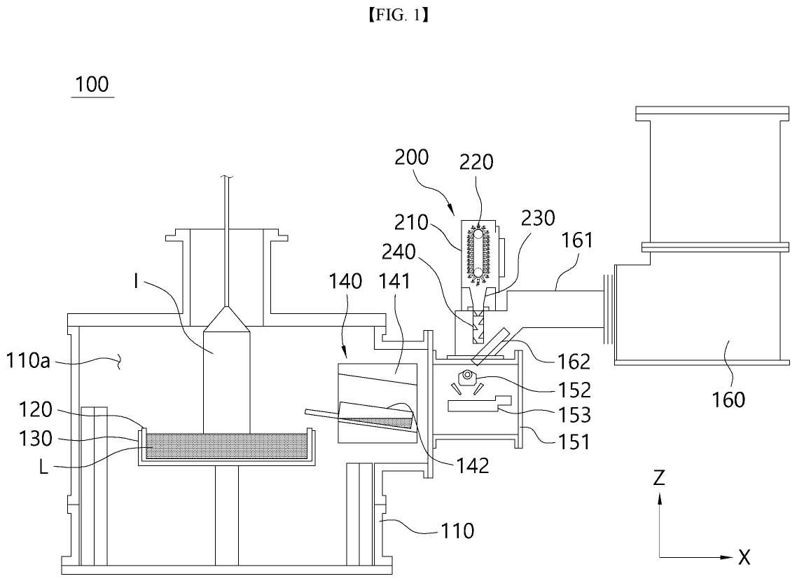

FIG. 1 is a view schematically showing the ingot growing apparatus according to an exemplary embodiment of the present invention.

Referring to FIG. 1, the ingot growing apparatus 100 according to an exemplary embodiment of the present invention includes a growth furnace 110, a main crucible 120, a susceptor 130, a preliminary melting part 140, a transfer part 151, a silicon supply part 160 and a dopant supply part 200.

The growth furnace 110 has an inner space 110a which is maintained in a vacuum state, and an ingot I is grown in the inner space 110a.

The growth furnace 110 is provided with a vacuum pump (not illustrated) and an inert gas supply part (not illustrated). The vacuum pump maintains the inner space 110a in a vacuum atmosphere. In addition, the inert gas supply part supplies an inert gas to the inner space 110a. The inert gas may be, for example, argon (Ar).

The main crucible 120 is accommodated in the inner space 110a of the growth furnace 110. The main crucible 120 accommodates molten silicon L.

In addition, the main crucible 120 is made of a quartz material. However, the main crucible 120 is not limited to being made of a quartz material, and it may be made of various materials that have heat resistance at a temperature of about 1,400° C. or higher and withstand rapid temperature changes.

In this case, when the single-crystal seed is pulled upward in a state of being in contact with molten silicon L contained in the main crucible 120, an ingot I having a predetermined diameter is grown along a direction in which the ingot I is pulled through a crown process in which the diameter of the ingot I is increased to approach the target diameter of the ingot I.

The growth furnace 110 is provided with the susceptor 130 which is formed to surround an outer side surface of the main crucible 120.

The susceptor 130 supports the main crucible 120. The inner side surface of the susceptor 130 has a shape corresponding to the outer side surface of the main crucible 120.

In addition, the susceptor 130 is made of a graphite material. In addition, the susceptor 130 is not limited to being made of a graphite material, and it may be made of various materials having strong heat resistance and conductive properties.

Accordingly, even if the main crucible 120 is made of a quartz material and is deformed at a high temperature, the susceptor 130 surrounds and supports the main crucible 120 such that the main crucible 120 maintains a state of accommodating molten silicon M.

In addition, a heating part (not illustrated) for heating the susceptor 130 is provided in the growth furnace 110. The heating part receives electric power and generates electromagnetic induction to heat the susceptor 130. In addition, the heating part is not limited to being implemented in an induction heating method, and it may be implemented in a resistance heating method in which electric power is supplied and heat is directly generated.

The preliminary melting part 140 receives a solid silicon material and a dopant and melts the same into molten silicon. In addition, the preliminary melting part 140 is provided with a preliminary crucible 142 which accommodates molten silicon.

In this case, the preliminary crucible 142 is made of a quartz material. However, the preliminary crucible 142 is not limited to being made of a quartz material, and it may be made of various materials that have heat resistance at a temperature of about 1,400° C. or higher and withstand rapid temperature changes.

In addition, the preliminary crucible 142 is provided to be positioned between a first position in which the solid silicon material is accommodated and the accommodated solid silicon material is melted, and a second position which is tilted such that the molten silicon is supplied to the main crucible 120. To this end, a preliminary crucible moving module (not illustrated) for moving the position of the preliminary crucible 142 is provided in the preliminary melting part 140. The preliminary crucible moving module tilts one side of the preliminary crucible 142 toward the main crucible 120 and supplies the molten silicon accommodated in the preliminary crucible 142 to the main crucible 120. Herein, the side from the preliminary melting part 140 toward the main crucible 120 is referred to as one side, and the opposite side is referred to as the other side.

The transfer part 151 is disposed outside the growth furnace 110. In addition, the transfer part 151 is disposed adjacent to the preliminary melting part 140. The transfer part 151 transfers the solid silicon material and the dopant to the preliminary crucible 142.

In this case, the transfer part 151 includes a weight measuring part 152 for measuring the weights of the solid silicon material and the dopant to be supplied to the preliminary crucible 142. In addition, the solid silicon material and the dopant are measured by the weight measuring part 152, and the solid silicon material and the dopant are introduced into a basket 153 in set quantities.

In this case, after the solid silicon material and the dopant accommodated in the basket 153 are moved to an upper side of the preliminary crucible 142, the solid silicon material and the dopant are introduced into the preliminary crucible 142.

The silicon supply part 160 is formed to be connected to an upper side of the transfer part 151. The silicon supply part 160 transfers the solid silicon material to the weight measuring part 152. In this case, the silicon supply part 160 is provided with a connection part 161 which is connected to an upper side of the transfer part 151. In addition, an inclined part 162 is provided inside the connection part 161 such that the solid silicon material is smoothly transferred. Accordingly, the solid silicon material and the dopant are transferred to the weight measuring part 152 along the inclined part 162.

The dopant supply part 200 is disposed on an upper side of the transfer part 151 and supplies the dopant to the transfer part 151 according to a concentration of the dopant melted in the main crucible 120. The detailed description of the dopant supply part 200 will be described below with reference to the drawings.

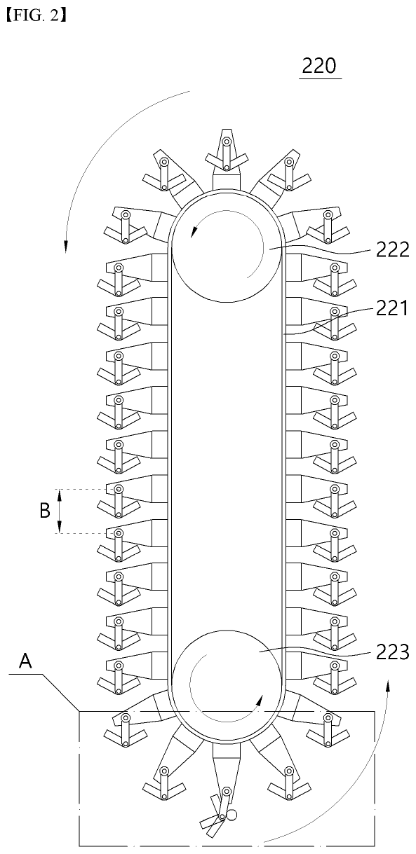

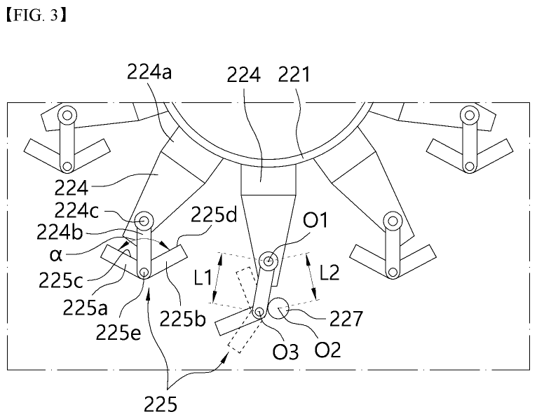

FIG. 2 is a diagram showing the dopant transfer part illustrated in FIG. 1, and FIG. 3 is an enlarged view of A indicated in FIG. 2.

Referring to FIGS. 2 and 3, the dopant supply part 200 includes a body part 210 (refer to FIG. 1) and a dopant transfer part 220.

The body part 210 (refer to FIG. 1) is disposed on an upper side the transfer part 151 (refer to FIG. 1). In addition, a door (not illustrated) that is opened and closed is provided on one side of the body part 210. When the door is opened, the dopant is supplied into the body part 210 from the outside.

The dopant transfer part 220 is disposed inside the body part 210. In addition, the dopant transfer part 220 accommodates the dopant and controls supply of the dopant.

In this case, the dopant transfer part 220 includes a first rotation part 222, a second rotation part 223, a belt 221, a plurality of dopant supporting parts 224 and a plurality of dopant accommodating parts 225.

The first rotation part 222 is disposed inside the body part 210. In addition, the first rotation part 222 is made of a cylindrical shape. In addition, the first rotation part 222 is rotated in a clockwise direction or counterclockwise direction. In this case, the first rotation part 222 may rotate at a constant speed or stop rotating.

The second rotation part 223 is disposed to be spaced apart from the first rotation part 222 inside the body part 210. In addition, the second rotation part 223 has the same shape as the first rotation part 222. For example, the second rotation part 223 has a cylindrical shape like the first rotation part 222.

In this case, the second rotation part 223 is rotated in the same direction as the first rotation part 222. In addition, the rotational speed of the second rotational part 223 is the same as the rotational speed of the first rotational part 222.

The belt 221 has a belt shape. In addition, the belt 221 is in contact with the first rotation part 222 and the second rotation part 223. Accordingly, the belt 221 is rotated in a clockwise direction or counterclockwise direction by the first rotation part 222 and the second rotation part 223.

In this case, the belt 221 is made of a rubber material. However, the belt 221 is not limited to being made of a rubber material, and it may be made of various materials having elasticity. In addition, according to various exemplary embodiments of the present invention, the belt 221 may be formed in a chain shape. In addition, when the belt 221 is formed in a chain shape, the outer side surface of the first rotation part 222 and the outer side surface of the second rotation part 223 may be formed in shapes corresponding to the belt 221 so as to be in smooth contact with the belt 221.

The plurality of dopant supporting parts 224 are disposed on an outer side of the belt. In addition, the plurality of dopant supporting parts 224 are disposed to be spaced apart from each other. In this case, as illustrated in FIG. 3, the plurality of dopant supporting parts 224 include a first supporting part 224a, a first rotation shaft 224c and a second supporting part 224b.

The first supporting part 224a is coupled to an outer side of the belt 221.

The first rotation shaft 224c is disposed on one side of the first supporting part 224a. In this case, as illustrated in FIG. 2, the plurality of dopant supporting parts 224 are provided such that the first rotation shafts 224c are spaced apart from each other at regular intervals B.

The second supporting part 224b is rotatably connected to the first rotation shaft 224c. Accordingly, the second supporting part 224b is rotated toward the direction of gravity.

The plurality of dopant accommodating parts 225 are rotatably connected to each of the plurality of dopant supporting parts 224 and accommodate the dopant. In this case, the plurality of dopant accommodating parts 225 include a first accommodating part 225a, a second accommodating part 225b and a second rotation shaft 225e.

The first accommodating part 225a is formed in a flat plate shape.

The second accommodating part 225b extends from the first accommodating part 225b and is formed to be inclined at a predetermined angle α with respect to the first accommodating part 225b. In this case, the second accommodating part 225b is formed symmetrically with the first accommodating part 225a. Accordingly, the dopant is seated on one surface 225c of the first accommodating part 225a and one surface 225d of the second accommodating part 225b.

The second rotation shaft 225e is disposed between the first accommodating part 225a and the second accommodating part 225b, and is rotatably connected to the second supporting part 224b. In addition, the dopant accommodating part 225 is rotated in a clockwise direction or counterclockwise direction about the second rotation shaft 225e.

Accordingly, when the belt 221 rotates between the first rotation part 222 and the second rotation part 223, the dopant is stably accommodated in the dopant accommodating part 225.

In addition, the dopant transfer part 220 is provided with a locking part 227 which is disposed on a lower side the body part 210 and contacts the dopant accommodating part 225 to rotate the dopant accommodating part 225.

In this case, when the dopant supporting part 224 rotates along the belt 221 and is adjacent to the locking part 227, the distance L1 between the center O1 of the first rotational shaft 224c and the center O2 of the second rotational shaft 225e is greater than the distance L2 between the center O1 of the first rotation shaft 224c and the center O3 of the locking part 227. For example, the distance L1 between the center O1 of the first rotation shaft 224c and the center O2 of the second rotation shaft 225e may be 8.8 mm, and the distance L2 between the center O1 of the first rotation shaft 224c and the center O3 of the locking part 227 may be 7.7 mm.

The process of rotating the dopant accommodating part 225 and falling in the direction of gravity will be described below with reference to the drawings.

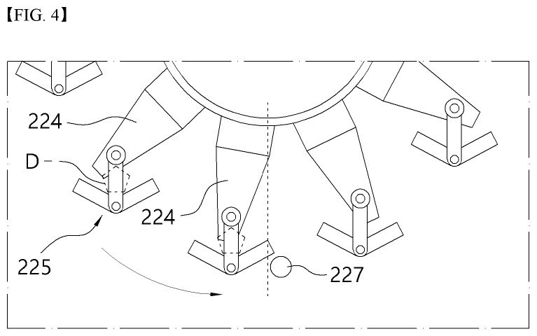

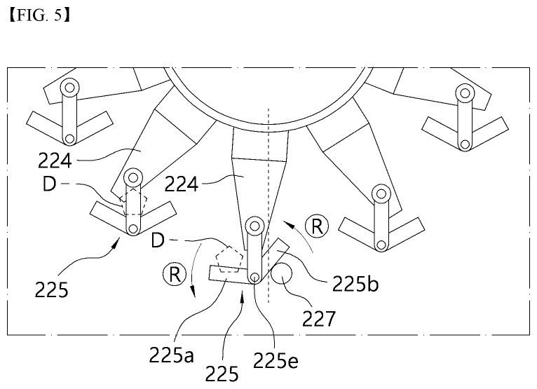

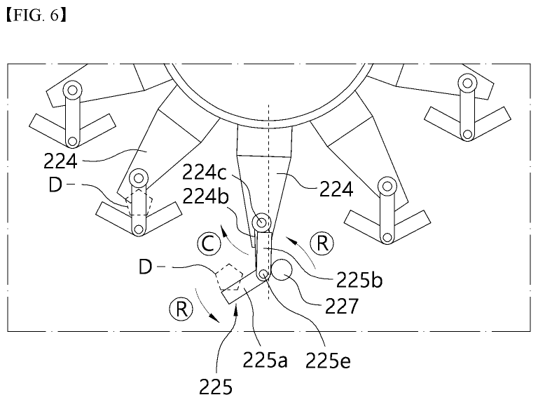

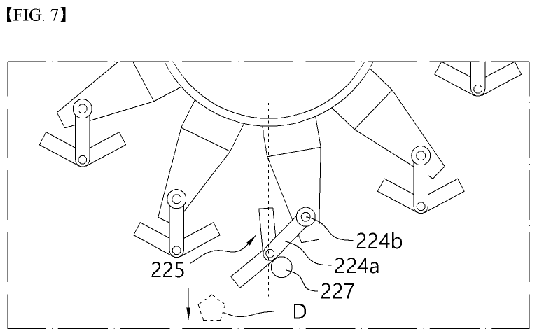

FIG. 4 is a view showing a state in which the dopant supporting part is adjacent to the locking part, FIG. 5 is a view showing a state in which the dopant accommodating part contacts the locking part, FIG. 6 is a view showing how the dopant accommodating part rotates, and FIG. 7 is a diagram showing a process in which the dopant falls from the dopant accommodating part.

First of all, as illustrated in FIG. 4, the dopant D is accommodated in the dopant accommodating part 225. In this case, when the belt is rotated, the dopant supporting part 224 is adjacent to the locking part 227.

In addition, as illustrated in FIG. 5, the dopant accommodating part 225 comes into contact with the locking part 227.

In this case, when the second accommodating part 225b is rotated in a counterclockwise direction by the locking part 227, the first accommodating part 225a is inclined toward the direction of gravity.

In addition, as illustrated in FIG. 6, when the belt continues to rotate, the first accommodating part 225a is rotated in a clockwise direction about the second rotating shaft 225e. In this case, the second supporting part 224b also rotates in a clockwise direction about the first rotation shaft 224c.

Finally, as illustrated in FIG. 7, when the belt continues to rotate, the dopant D is separated from the dopant accommodating part 225 and falls along the direction of gravity.

In addition, the second supporting part 224b also rotates in a clockwise direction about the first rotation shaft 224c such that the dopant accommodating part 225 moves through the upper side of the locking part 227.

As such, the dopant supply part 220 (refer to FIG. 1) supplies the dopant D to the transfer part 151 at intervals of time such that the supply of the dopant D may be precisely controlled.

In addition, as the rotation speed of the belt 221 (refer to FIG. 2) is adjusted, the supply of the dopant D may be precisely controlled.

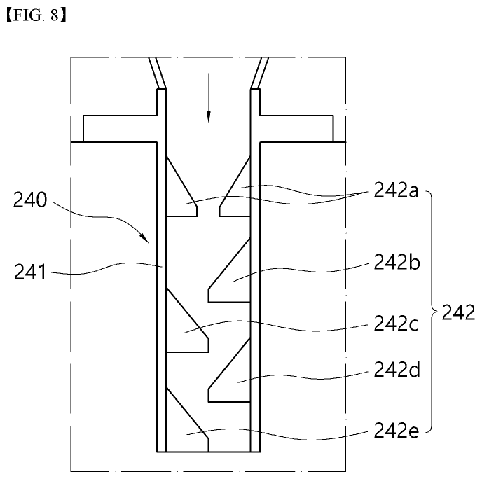

FIG. 8 is a view showing the fall reducing part illustrated in FIG. 1.

Referring to FIGS. 1 and 8, the dopant supply part 200 is provided with a speed reducing part 240 that reduces the falling speed of the dopant D falling in the direction of gravity from the dopant accommodating part 225 (refer to FIG. 3).

The speed reducing part 240 extends from a lower side of the body part 210. In addition, the speed reducing part 240 includes a discharge pipe 241 and a plurality of protrusions 242.

The discharge pipe 241 is connected to a lower side of the body part 210. The discharge pipe 241 has a cylindrical shape.

The plurality of protrusions 242 are formed to protrude from an inner side surface of the discharge pipe 241. The plurality of protrusions 242 may contact the dopant D falling in the direction of gravity.

In this case, the plurality of protrusions 242 include a plurality of first protrusions 242a which are formed to narrow along the direction of gravity and a plurality of second protrusions 242b which are disposed to be spaced apart from the plurality of first protrusions.

The plurality of first protrusions 242a are located on an upper side of the discharge pipe 241.

The plurality of second protrusions 242b are disposed to be spaced apart from each other along the direction of gravity. For example, the plurality of second protrusions 242b are disposed at different positions on an inner side surface of the discharge pipe 241.

Accordingly, the dopant D does not fall directly onto the transfer part 151, but since the falling speed is reduced as it contacts the plurality of protrusions 242, the dopant D is prevented from falling to the transfer part 151 and splashing.

As described above, the preferred exemplary embodiments according to the present invention have been reviewed, and the fact that the present invention can be embodied in other specific forms in addition to the above-described exemplary embodiments without departing from the spirit or scope is a matter that is apparent to those of ordinary skill in the art. Therefore, the exemplary embodiments described above are to be regarded as illustrative rather than restrictive, and accordingly, the present invention is not limited to the above description, but may be changed within the scope of the appended claims and their equivalents.

1. An ingot growing apparatus, comprising:
a growth furnace in which a main crucible accommodating molten silicon for growing an ingot is disposed;
a preliminary melting part which receives and melts a solid silicon material and a dopant, and has a preliminary crucible that supplies the molten silicon to the main crucible;
a transfer part which transfers the solid silicon material and the dopant to the preliminary crucible;
a silicon supply part which supplies the solid silicon material to the transfer part; and
a dopant supply part which is disposed on an upper side of the transfer part and supplies the dopant to the transfer part according to a concentration of the dopant melted in the main crucible.

2. The ingot growing apparatus of claim 1, wherein the dopant supply part comprises:
a body part which is disposed on an upper side of the transfer part; and
a dopant transfer part which is disposed inside the body part and accommodates the dopant to control supply of the dopant.

3. The ingot growing apparatus of claim 2, wherein the dopant transfer part comprises:
a first rotation part which is disposed inside the body part and rotated in a clockwise or counterclockwise direction;
a second rotation part which is disposed to be spaced apart from the first rotation part inside the body part and rotated in the same direction as the first rotation part;
a belt which is in contact with the first rotation part and the second rotation part and rotated by the first rotation part and the second rotation part;
a plurality of dopant supporting parts which are disposed on an outer side of the belt; and
a plurality of dopant accommodating parts which are rotatably connected to each of the plurality of dopant supporting parts and accommodate the dopant

4. The ingot growing apparatus of claim 3, wherein the dopant transfer part further comprises a locking part which is disposed on a lower side of the body part and contacts the dopant accommodating part to rotate the dopant accommodating part.

5. The ingot growing apparatus of claim 4, wherein the dopant supporting part comprises:
a first support part which is coupled to an outer side of the belt;
a first rotational shaft which is disposed on one side of the first support part; and
a second support part which is rotatably connected to the first rotation shaft.

6. The ingot growing apparatus of claim 5, wherein the dopant accommodating part comprises:
a first accommodating part which is made of a flat plate shape;
a second accommodating part which extends from the first accommodating part and is formed to be inclined at a predetermined angle with the first accommodating part; and
a second rotational shaft which is rotatably connected to the second support part and disposed between the first accommodating part and the second accommodating part,
wherein the dopant accommodating part is rotated in a clockwise direction or counterclockwise direction about the second rotational shaft.

7. The ingot growing apparatus of claim 6, wherein when the dopant supporting part rotates along the belt and abuts the locking part, the distance between the center of the first rotational shaft and the center of the second rotational shaft is greater than the distance between the center of the first rotational shaft and the center of the locking part.

8. The ingot growing apparatus of claim 7, wherein the speed reducing part comprises:
a discharge pipe which is connected to a lower side of the body part; and
a plurality of protrusions which protrude from an inner side surface of the discharge pipe and contact the dopant falling in the direction of gravity.

9. The ingot growing apparatus of claim 8, wherein the plurality of protrusions comprise:
a plurality of first protrusions which are formed to narrow along the direction of gravity; and
a plurality of second protrusions which are disposed to be spaced apart from the plurality of first protrusions and are disposed to be spaced apart from each other along the direction of gravity.
